(19) United States
(12) Patent Application Publication
(10) Pub. No.: US 2012/0305043 A1
(43) Pub. Date: Dec. 6, 2012

(54) THERMOELECTRIC DEVICES WITH REDUCTION OF INTERFACIAL LOSSES

(75) Inventors: Dmitri Kossakovski, S. Pasadena, CA (US); Douglas T. Crane, Altadena, CA (US)

(73) Assignee: Amerigon, Inc., Northville, MI (US)

(21) Appl. No.: 13/488,989

(22) Filed: Jun. 5, 2012

Related U.S. Application Data
(60) Provisional application No. 61/493,906, filed on Jun. 6, 2011.

(51) Int. Cl. H01L 35/28

(52) U.S. Cl. 136/200

(57) ABSTRACT

In certain embodiments, a thermoelectric system can include a first thermoelectric assembly and a second thermoelectric assembly. Both the first and second thermoelectric assemblies can be configured to receive heat from at least one heat source and to transmit heat to at least one heat sink. The first and second thermoelectric assemblies can be in electrical communication with one another. The thermoelectric system can further include at least one electrically insulating element mechanically coupled to the first thermoelectric assembly and to the second thermoelectric assembly. The at least one electrically insulating element is not in a thermal path of either (i) heat flow from the at least one heat source to either the first thermoelectric assembly or the second thermoelectric assembly or (ii) heat flow to the at least one heat sink from either the first thermoelectric assembly or the second thermoelectric assembly.

### CROSS-REFERENCE TO RELATED APPLICATIONS

This application claims the benefit of U.S. Provisional Application No. 61/493,906 filed Jun. 6, 2011, which is incorporated herein in its entirety by reference. This application is related to U.S. patent application Ser. No. ______, entitled “Cartridge-Based Thermoelectric Devices,” filed on even date herewith, which is incorporated in its entirety by reference herein and U.S. patent application Ser. No. ______, entitled “Systems and Methods For Reducing Current and Increasing Voltage In Thermoelectric Systems,” filed on even date herewith, which is incorporated in its entirety by reference herein.

### STATEMENT REGARDING FEDERALLY SPONSORED R&D

The U.S. Government may claim to have certain rights in this invention or parts of this invention under the terms of Contract No. DOE DE-FC26-04NT42279.

### BACKGROUND

1. Field

The present application relates to thermoelectric systems and methods of operating thermoelectric systems for either power generation or heating and cooling.

2. Description of the Related Art

Thermoelectric (TE) devices can be operated in either heating/cooling or power generation modes. In the former, electric current is passed through the device to pump the heat from one side to the other side. In the latter, a heat flux driven by a temperature gradient across the device is converted into electricity. In both modalities, the performance of the device is largely determined by the figure of merit of the TE material and by the parasitic (dissipative) losses throughout the system.

### SUMMARY

In certain embodiments, a thermoelectric system is provided. The thermoelectric system can include a first thermoelectric assembly configured to receive heat from at least one heat source and to transmit heat to at least one heat sink. The thermoelectric system can also include a second thermoelectric assembly configured to receive heat from the at least one heat source and to transmit heat to the at least one heat sink. The second thermoelectric assembly can be in electrical communication with the first thermoelectric assembly. The thermoelectric system can further include at least one electrically insulating element mechanically coupled to the first thermoelectric assembly and to the second thermoelectric assembly. The at least one electrically insulating element is not in a thermal path of either (i) heat flow from the at least one heat source to either the first thermoelectric assembly or the second thermoelectric assembly or (ii) heat flow to the at least one heat sink from either the first thermoelectric assembly or the second thermoelectric assembly.

In some embodiments, a thermoelectric system is provided that can include a plurality of thermoelectric assemblies each configured to receive heat from at least one heat source and to transmit heat to at least one heat sink. The plurality of thermoelectric assemblies can be in electrical communication with one another and can include a plurality of electrically insulating elements. The plurality of electrically insulating elements can each be mechanically coupled to at least two thermoelectric assemblies of the plurality of thermoelectric assemblies. The plurality of electrically insulating elements is not in a thermal path of either (i) heat flow from the at least one heat source to the plurality of thermoelectric assemblies or (ii) heat flow to the at least one heat sink from the plurality of thermoelectric assemblies.

### BRIEF DESCRIPTION OF THE DRAWINGS

Various embodiments are depicted in the accompanying drawings for illustrative purposes, and should in no way be interpreted as limiting the scope of the thermoelectric assemblies or systems described herein. In addition, various features of different disclosed embodiments can be combined with one another to form additional embodiments, which are part of this disclosure. Any feature or structure can be removed, altered, or omitted. Throughout the drawings, reference numbers may be reused to indicate correspondence between reference elements.

FIG. 1 is a generalized block diagram view of an example TE assembly in accordance with certain embodiments described herein;

FIG. 2 is an example TE system that includes a plurality of TE assemblies connected in series electrically and in parallel thermally in accordance with certain embodiments described herein;

FIG. 3 is an example TE system that includes a plurality of TE assemblies physically attached to common substrates on both sides of the TE assemblies;

FIG. 4 is an example TE system that includes a plurality of TE assemblies physically attached to electrically isolating common substrates that are continuous along the length of the TE system on two sides of the TE system;

FIG. 5 is an example TE system that includes a plurality of TE assemblies physically attached to electrically isolating common substrates that are continuous along the length of the TE system on one side of the TE system and localized to the TE assembly level on a second side of the TE system;

FIG. 6 is an example TE system that includes a plurality of TE assemblies and at least one electrically insulating element not in the thermal path of heat flow from a heat source to the TE assemblies in accordance with certain embodiments described herein;

FIG. 7 is an example TE system that includes a plurality of TE assemblies and at least one electrically insulating element not in the thermal path of heat flow to a heat sink from the TE assemblies in accordance with certain embodiments described herein;

FIG. 8 is an example TE system that includes a plurality of TE assemblies and at least one electrically insulating element not in the thermal path of heat flow from a heat source to the TE assemblies and not in the thermal path of heat flow to a heat sink from the TE assemblies in accordance with certain embodiments described herein;

FIG. 9 is an example TE system that includes a plurality of TE assemblies and at least one monolithic electrically insulating element that bridges the first and second side of each TE assembly in accordance with certain embodiments described herein;

FIG. 10 is an example TE system that includes a plurality of TE assemblies, each TE assembly having a plurality of TE elements and a plurality of first and second heat exchangers, with first and second electrically insulating elements sandwiched between the TE assemblies in accordance with certain embodiments described herein; and

FIG. 11 is an example TE system that includes a plurality of TE elements and a plurality of first and second heat exchangers in accordance with certain embodiments described herein.

### DETAILED DESCRIPTION

Certain embodiments herein disclose system level solutions that minimize the parasitic or dissipative losses, and therefore improve system level efficiency of the TE devices. While power generation devices are disclosed as examples in some embodiments, the innovations are generalized to heating/cooling modalities as well.

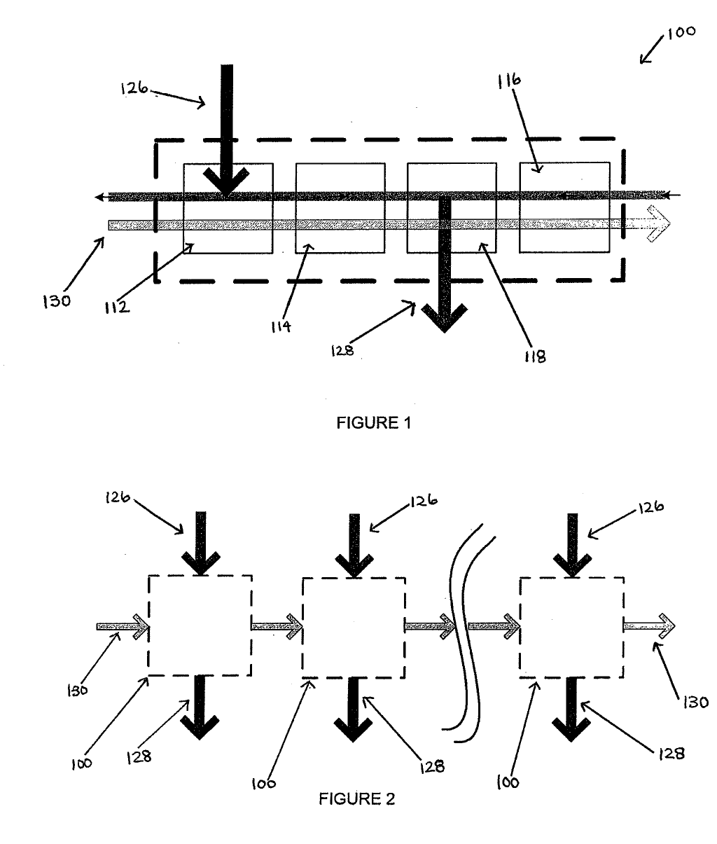

In a traditional TE device, the heat flux passes or flows from one side of the device to another side. For example, in a power generation TE device, the heat flows from the hot side to the cold side. FIG. 1 shows a generalized block diagram view of an example TE assembly 100, which can be an elementary cell of a TE system. Each TE assembly 100 can include at least one hot side heat exchanger 112, one or more p-type TE elements 114, one or more n-type TE elements 116, at least one cold side heat exchanger 118 and electrical contacts (not shown) creating the circuit through which electrical current 130 flows during operation. The p- or n-type TE elements 114, 116 shown in FIG. 1 can include either a single such element or a plurality of such elements connected in parallel with one another. The TE assembly 100 receives heat flow 126 from the heat source (not shown) and heat flow 128 flows from the TE assembly 100 to the heat sink (not shown).

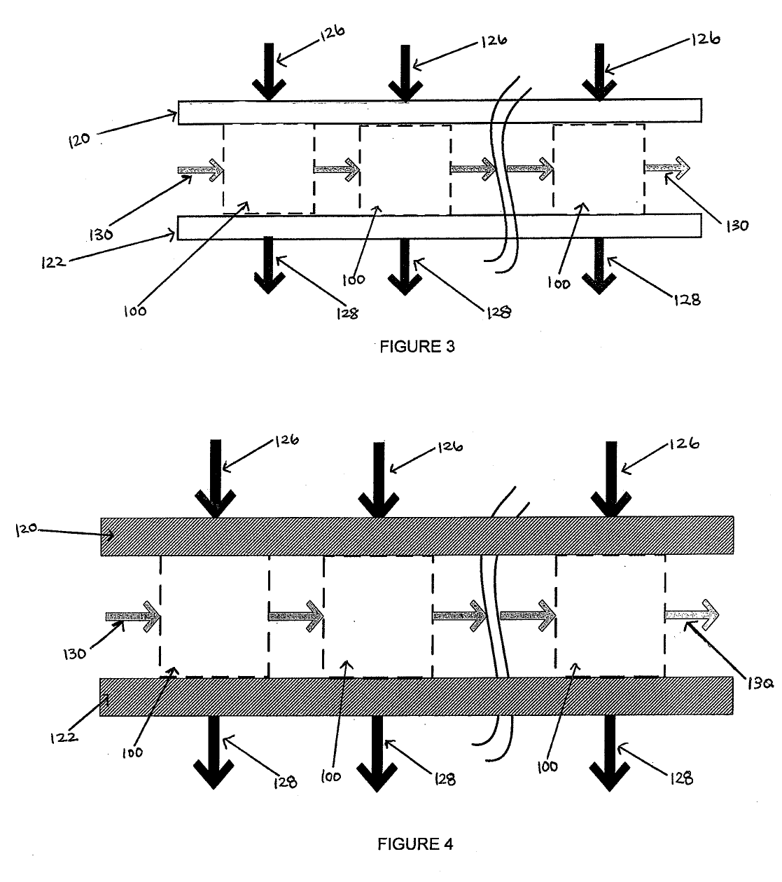

In the vast majority of practical devices, there is more than one repeating TE assembly 100. FIG. 2 schematically illustrates an example of such a device or system that comprises a plurality of TE assemblies 100 (e.g., 1, 2, 3 . . . up to N number of assemblies) connected in series electrical communication (shown schematically by the horizontal arrows for the electrical current 130) and in parallel thermal communication with one another (shown schematically by the vertical arrows for the heat flow 126, 128). In certain other configurations, the TE assemblies 100 can be in parallel electrical communication with one another. Further, as schematically illustrated by FIG. 3, the TE assemblies 100 can be physically or mechanically attached to a common hot side substrate 120, a common cold side substrate 122, or both.

Electrical current 130 can flow through the TE assemblies 100 of FIGS. 1-3 in series. At the same time, the heat flow 126, 128 through the TE assemblies 100 can be in thermal paths that are parallel to one another and can flow through the common hot and/or cold side substrates 120, 122 of the TE assemblies 100.

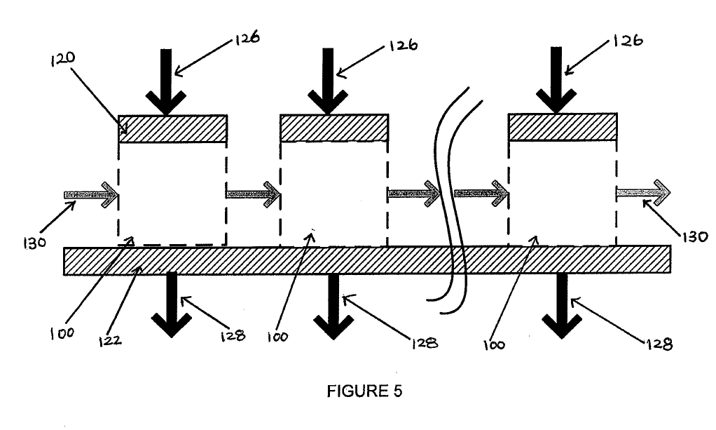

Certain such configurations provide electrical isolation between adjacent TE assemblies 100 to avoid electrical shorting through the common substrate. A common solution for providing this electrical insulation has been to use ceramic or plastic substrates that electrically isolate the TE assemblies from one another. For example, typical commercial thermoelectric modules can use alumina or aluminum nitride ceramics as substrates. The substrate or substrates providing the electrical isolation are shown by hashed lines in FIG. 4 (with substrates 120, 122 that are continuous along the length of two sides of the device) and in FIG. 5 (with a hot side substrate 120 that is localized to the TE assembly level on one side of the device and a cold side substrate 122 that is continuous along the length of the other side of the device).

Typically, dielectric interfaces such as ceramics, plastics, epoxies, glues or others, have poor thermal conductivity relative to metals and electrically conductive interfaces. The poor thermal conductivity results in efficiency losses of the TE device by virtue of heat dissipation in undesirable locations of the device. For example, the electrically insulating material may reduce the heat flow 126 reaching the TE elements of the TE device from the heat source and may reduce the heat flow 128 reaching the heat sink from the TE device. Therefore, it is desirable to minimize or eliminate such interfaces in order to improve the efficiency of the TE device or system.

Certain embodiments described herein include electrically insulating elements, such as dielectric materials, layers or interfaces, that are positioned away from the thermal path of thermal flux or heat flow, while still preserving the desired electrical isolation between the TE assemblies in the device and other portions to eliminate alternate electrical current flow paths beyond the desired serial electrical current flow path through the TE elements of the TE assemblies.

A variety of embodiments of thermoelectric systems are described below to illustrate various configurations. The particular embodiments and examples are only illustrative and features described in one embodiment or example may be combined with other features described in other embodiments or examples. Accordingly, the particular embodiments and examples are not intended to be restrictive in any way.

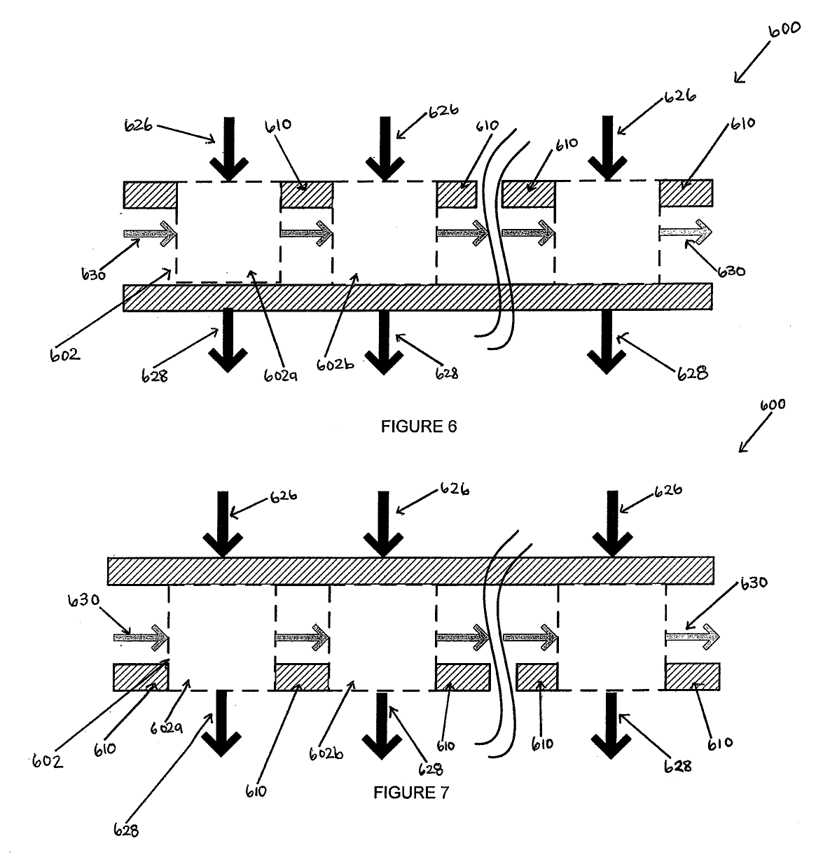

In certain embodiments, as schematically illustrated in FIGS. 6-8, a thermoelectric system 600 comprises a plurality of thermoelectric assemblies 602 (e.g. a first TE assembly 602a and a second TE assembly 602b) in electrical communication with each other. FIG. 1, as discussed above, schematically illustrates an example TE assembly 100 and some of its components compatible with certain embodiments described herein. Each TE assembly 602 of the TE system 600 can be configured to receive heat flow 626 from at least one heat source (not shown) and to transmit heat flow 628 to at least one heat sink (not shown). The thermoelectric system 600 can further comprise at least one electrically insulating element 610 mechanically coupled to at least two TE assemblies of the plurality of TE assemblies 602 (e.g., the first and second TE assemblies 602a, 602b).

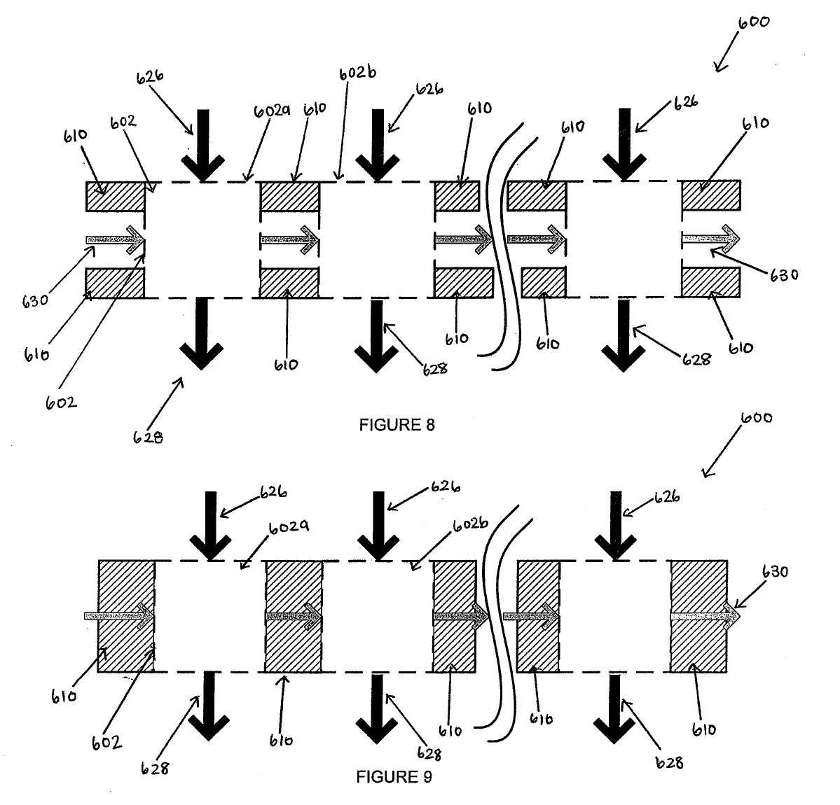

In some embodiments, as shown in FIG. 6, the at least one electrically insulating element 610 is not in a thermal path of heat flow 626 from the at least one heat source (not shown) to the plurality of TE assemblies 602 (e.g., the first TE assembly 602a and the second TE assembly 602b). In some embodiments, as shown in FIG. 7, the at least one electrically insulating element 610 is not in a thermal path of heat flow 628 to the at least one heat sink (not shown) from the plurality of TE assemblies 602 (e.g., the first TE assembly 602a and the second TE assembly 602b). In some embodiments, as shown in FIG. 8, the at least one electrically insulating element 610 is not in a thermal path of the heat flow 626 from the at least one heat source (not shown) to the plurality of TE assemblies 602 (e.g., the first TE assembly 602a and the second TE assembly 602b) and the at least one electrically insulating element 610 is not in a thermal path of the heat flow 628 to the at least one heat sink (not shown) from the plurality of TE assemblies 602 (e.g., the first TE assembly 602a and the second TE assembly 602b). In some embodiments, the at least one electrically insulating element 610 is positioned relative to the plurality of TE assemblies 602 (e.g., the first TE assembly 602a and the second TE assembly 602b) such that the at least one electrically insulating element 610 does not impede the heat flow 626 from the at least one heat source (not shown) to the plurality of TE assemblies 602 (e.g., the first TE assembly 602a and the second TE assembly 602b) and the at least one electrically insulating element 610 does not impede the heat flow 628 to the at least one heat sink (not shown) from the plurality of TE assemblies 602 (e.g., the first TE assembly 602a and the second TE assembly 602b).

The TE assemblies 602 can each comprise one or more cells, TE elements, and/or TE modules. For example, the TE assembly 602 can each comprise one or more structures as shown in FIG. 1. The one or more cells of a TE assembly 602 can be in electrical communication with each other. In some embodiments, each cell can include a first side that is in direct or indirect thermal communication with a heat source and receives heat from the heat source. Each cell can also transmit heat to a heat sink that is in direct or indirect thermal communication with a second side of the cell.

Examples of heat sources (not shown) include but are not limited to sources of heat generated from a combustion process, geothermal source, or radioactive decay (e.g., heated water or gas). Heat sinks (not shown) can include but are not limited to heat exchangers or fins made of copper or aluminum and that are in thermal communication with a material at a lower temperature than that of the heat source (e.g. cooling water or gas such as ambient air). The at least one electrically insulating element 610 can be coupled to the plurality of TE assemblies 602 (e.g., the first and second TE assemblies 602a, 602b) by an adhesive, nuts and bolts, or any other type of mechanical or physical coupling.

The at least one electrically insulating element 610 can comprise (e.g., be constructed or made from) one or more materials selected from a group comprising ceramic, plastic, epoxy, and glue. In some embodiments, the materials can comprise alumina or aluminum nitride ceramic. In other embodiments, the materials can further comprise polytetrafluoroethylene (PTFE), polyimide, silicone rubbers, and polyether ether ketone (PEEK). In some embodiments, the at least one electrically insulating element 610 is substantially thermally insulating and is in thermal communication with at least one heat source (not shown) and at least one heat sink (not shown).

One example of an electrically insulating element 610 is at least one dielectric layer. One way to position the dielectric layer or layers away from the path of thermal flux, and still preserve the desired electrical isolation in the TE system 600 is to position the at least one dielectric layer between the adjacent TE assemblies 602 but not between the TE assemblies 602 and the heat source (not shown) and/or the heat sink (not shown). As described above, FIG. 6 shows a schematic implementation of such an arrangement on a first side (e.g., hot side) of the TE system 600. In the example TE system 600 shown in FIG. 6, the heat flow 626 can be unimpeded from the heat source (not shown) into and/or through each TE assembly 602 of the plurality of TE assemblies 602. There are no temperature drops due to an electrically insulating material in the heat flux path, since the at least one electrically insulating element 610 is not positioned in or blocking the path of the heat flow 626 from the heat source (not shown) to the TE assemblies 602. Therefore the temperature on the hot side of the TE system 600 is maximized, resulting in an increased efficiency of the TE system 600.

In some embodiments, as shown in FIG. 7, a similar approach can be used with the at least one electrically insulating element 610 positioned between the adjacent TE assemblies 602 (e.g., the first TE assembly 602a and the second TE assembly 602b) on a second side (e.g., cold side) of the TE system 600. As shown in FIG. 7, the heat flow 628 can be unimpeded from and/or through at least one TE assembly 602 of the plurality of TE assemblies 602 to the heat sink (not shown). There are no temperature drops due to an electrically insulating material in the heat flux path since the at least one electrically insulating element 610 is not positioned in or blocking the path of the heat flow 628 from the TE assemblies 602 to the heat sink (not shown). Therefore, the temperature on the cold side of the TE system 600 is maximized, resulting in an increased efficiency of the TE system 600.

In other embodiments, as shown in FIG. 8, the at least one electrically insulating element 610 is separate from the thermal path through the TE assemblies 602 on each of the two sides (e.g., hot side and cold side) of the TE system 600. Therefore, the heat flow 626 can be unimpeded from the heat source (not shown) into and/or through at least one TE assembly 602 (e.g., each TE assembly 602) and the heat flow 628 can be unimpeded to and/or through at least one TE assembly 602 (e.g., each TE assembly 602) to a heat sink. The temperature on both sides of the system can then be maximized, resulting in an increased efficiency of the TE system 600. In some embodiments, one side of the TE system 600 can be a hot side while the second side can be a cold side or vice versa.

In FIGS. 6-8, the at least one electrically insulating element 610 is shown schematically as comprising multiple portions (e.g., a first portion on a first side near the heat source and a second portion on a second side near the heat sink). In certain embodiments, as in FIG. 8, the heat flows 626, 628 can be unimpeded from the hot side to the cold side of the TE system 600. In the case of a TE power generating device, this improvement translates into maximizing the delta T across the device and therefore improved efficiency of conversion of heat into electricity. In the case of a TE heating/cooling device, efficiency is improved due to the TE materials maximizing delta T between the cold and hot sides of the device because of the absence of a parasitic temperature drop across heat dissipative interfaces.

In certain embodiments, as schematically illustrated by FIG. 9, a monolithic electrically insulating element 610 (e.g., dielectric substrate) bridges or extends between the first side and the second side of each TE assembly 602. Such an arrangement may be feasible if the thermal shorting losses (heat flowing from one side to another side through the substrate, bypassing the TE assembly 602) are negligible or can be traded for the increased robustness of the monolithic structure.

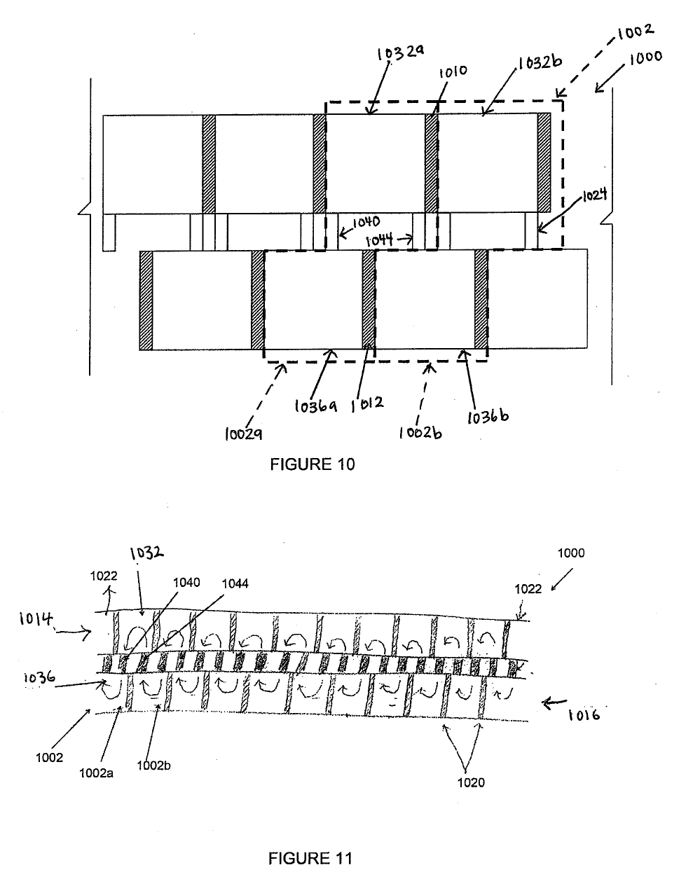

FIG. 10 schematically illustrates a portion of an example TE system 1000 in accordance with certain embodiments herein. In some embodiments, as schematically illustrated by FIG. 10, the TE system 1000 can comprise a plurality of TE assemblies 1002 (e.g., a first TE assembly 1002a and a second TE assembly 1002b) each configured to receive heat from at least one heat source and to transmit heat to at least one heat sink. The TE assemblies 1002 of the plurality of TE assemblies 1002 are in electrical communication with one another. The TE system 1000 can further comprise a plurality of electrically insulating elements 1010, 1012 each mechanically coupled to at least two TE assemblies 1002 of the plurality of TE assemblies 1002. The plurality of electrically insulating elements 1010, 1012 is not in a thermal path of either (i) heat flow from the at least one heat source (not shown) to the plurality of thermoelectric assemblies 1002 or (ii) heat flow to the at least one heat sink (not shown) from the plurality of thermoelectric assemblies 1002.

For example, the plurality of electrically insulating elements 1010, 1012 can comprise at least a first electrically insulating element 1010 sandwiched between a first heat exchanger 1032a of a first thermoelectric assembly 1002a and a first heat exchanger 1032b of a second thermoelectric assembly 1002b. The plurality of electrically insulating elements 1010, 1012 can further comprise at least a second electrically insulating element 1012 sandwiched between a second heat exchanger 1036a of the first thermoelectric assembly 1002a and a second heat exchanger 1036b of the second thermoelectric assembly 1002b.

In certain embodiments, as schematically illustrated by FIG. 10, each TE assembly 1002 of the plurality of TE assemblies 1002 (e.g., the first TE assembly 1002a and the second TE assembly 1002b) of the TE system 1000 comprises a first heat exchanger 1032 in thermal communication with the at least one heat source (not shown), a second heat exchanger 1036 in thermal communication with the at least one heat sink (not shown), and at least one first TE element 1040 having a first doping type and in thermal communication and in electrical communication with both the first heat exchanger 1032 and the second heat exchanger 1036. Each TE assembly 1002 of the plurality of TE assemblies 1002 (e.g., the first and second TE assemblies 1002a, 1002b) can further comprise at least one second TE element 1044 having a second doping type that is different from the first doping type, and in thermal communication and electrical communication with the first heat exchanger 1032. In some embodiments, the at least one second TE element 1044 of the first TE assembly 1002a is in thermal and electrical communication with the second heat exchanger 1036 of the second TE assembly 1002b.

In certain embodiments, as schematically illustrated by FIG. 11, the TE system 1000 can include hot and cold fluids 1014, 1016 in thermal communication with the first heat exchangers 1032 and the second heat exchangers 1036, electrical shunts 1018 and electrically insulating layers 1020 or other electrically insulating elements sandwiched between adjacent heat exchangers. The first and second doping types can include or comprise p- and n-type elements. The first and second heat exchangers 1032, 1036 can comprise one or more electrically and thermally conductive materials (e.g., copper). For example, the first and second heat exchangers 1032, 1036 can comprise electrically and thermally conductive portions of fluid conduits through which the hot fluid and cold fluids 1014, 1016 can flow (as indicated by horizontal arrows oriented in opposite directions). Additionally, electrical current 1022 can flow in series through the TE system 1000 with a path as indicated by the arrows. The electrically insulating elements 1020 can comprise electrically insulating portions of the fluid conduits through which the hot fluid and the cold fluid flow.

In certain embodiments, improved mechanical stability of the TE system 1000 can be provided. Depending on the configuration of the TE system 1000, it may be advantageous, stability-wise, to position the electrically insulating elements 1010, 1012 or dielectric materials or layers away from the path of the heat flux through the TE assemblies 1002 so as to be between the TE assemblies 1002 (e.g., at the boundaries between the TE assemblies 1002). Typically, mechanical loads at such interfaces are caused by various factors including, mismatch of the coefficient of thermal expansion between the electrically insulating layers and adjacent material, compressive loads of the assembly, and thermal and mechanical shock during operating conditions. Depending on the position of the electrically insulating materials or layers relative to the TE assemblies 1002 and the heat flux, or other aspects of the device configuration, such a TE system 1000 with the electrically insulating elements 1010, 1012 may provide improved mechanical stability of the TE system 1000.

In a typical TE system (e.g. a module or device), a hot side has an electrically insulating common element that unites the hot sides of all the TE assemblies. Such an electrically insulating common element can also have a metallic heat exchanger affixed to it from the side of a heat carrying medium. Such a heat exchanger also bridges a plurality of TE assemblies mechanically, up to the limit of bridging all the TE assemblies. When exposed to operational temperature, the hot side expands and creates mechanical stresses in the device or system. The location of the electrically insulating materials or layers between the TE assemblies effectively shortens the uninterrupted length of the metallic heat exchanger to the scale of an individual assembly. This arrangement can advantageously reduce the mechanical loads caused by the thermal expansion of the hot side of the TE system.

Various embodiments have been described above. Although the invention has been described with reference to these specific embodiments, the descriptions are intended to be illustrative and are not intended to be limiting. Various modifications and applications may occur to those skilled in the art without departing from the true spirit and scope of the invention as defined in the appended claims.

What is claimed is:

1. A thermoelectric system comprising:
a first thermoelectric assembly configured to receive heat from at least one heat source and to transmit heat to at least one heat sink;
a second thermoelectric assembly configured to receive heat from the at least one heat source and to transmit heat to the at least one heat sink, the second thermoelectric assembly in electrical communication with the first thermoelectric assembly; and
at least one electrically insulating element mechanically coupled to the first thermoelectric assembly and to the second thermoelectric assembly, wherein the at least one electrically insulating element is not in a thermal path of either (i) heat flow from the at least one heat source to either the first thermoelectric assembly or the second thermoelectric assembly or (ii) heat flow to the at least one heat sink from either the first thermoelectric assembly or the second thermoelectric assembly.

2. The thermoelectric system of claim 1, wherein the at least one electrically insulating element is not in a thermal path of the heat flow from the at least one heat source to either the first thermoelectric assembly or the second thermoelectric assembly and the at least one electrically insulating element is not in a thermal path of the heat flow to the at least one heat sink from either the first thermoelectric assembly or the second thermoelectric assembly.

3. The thermoelectric system of claim 2, wherein the at least one electrically insulating element is positioned relative to the first thermoelectric assembly and the second thermoelectric assembly such that the at least one electrically insulating element does not impede the heat flow from the at least one heat source to either the first thermoelectric assembly or the second thermoelectric assembly and the at least one electrically insulating element does not impede the heat flow to the at least one heat sink from either the first thermoelectric assembly or the second thermoelectric assembly.

4. The thermoelectric system of claim 1, wherein each of the first thermoelectric assembly and the second thermoelectric assembly comprises:
a first heat exchanger in thermal communication with the at least one heat source;
a second heat exchanger in thermal communication with the at least one heat sink;
at least one first thermoelectric element having a first doping type and in thermal communication and in electrical communication with both the first heat exchanger and the second heat exchanger; and
at least one second thermoelectric element having a second doping type different from the first doping type, the at least one second thermoelectric element in thermal communication and in electrical communication with the second heat exchanger.

5. The thermoelectric system of claim 4, wherein the at least one second thermoelectric element of the first thermoelectric assembly is in thermal communication and in electrical communication with the first heat exchanger of the second thermoelectric assembly.

6. The thermoelectric system of claim 4, wherein at least one of the first heat exchanger and the second heat exchanger comprises copper.

7. The thermoelectric system of claim 4, wherein the at least one electrically insulating element comprises:
at least a first electrically insulating element sandwiched between the first heat exchanger of the first thermoelectric assembly and the first heat exchanger of the second thermoelectric assembly; and
at least a second electrically insulating element sandwiched between the second heat exchanger of the first thermoelectric assembly and the second heat exchanger of the second thermoelectric assembly

8. The thermoelectric system of claim 1, wherein the first thermoelectric assembly and the second thermoelectric assembly are in series electrical communication with one another.

9. The thermoelectric system of claim 1, wherein the at least one electrically insulating element comprises one or more materials selected from the group consisting of: ceramic, plastic, epoxy, and glue.

10. The thermoelectric system of claim 9, wherein the one or more materials comprises alumina or aluminum nitride ceramic.

11. The thermoelectric system of claim 9, wherein the one or more materials comprises one or more plastic materials selected from the group consisting of: polytetrafluoroethylene, polyimide, silicone rubbers, and polyether ether ketone.

12. The thermoelectric system of claim 1, wherein the at least one electrically insulating element is substantially thermally insulating and is in thermal communication with the at least one heat source and the at least one heat sink.

13. A thermoelectric system comprising:
a plurality of thermoelectric assemblies each configured to receive heat from at least one heat source and to transmit heat to at least one heat sink, the TE assemblies of the plurality of thermoelectric assemblies in electrical communication with one another; and
a plurality of electrically insulating elements each mechanically coupled to at least two thermoelectric assemblies of the plurality of thermoelectric assemblies, wherein the plurality of electrically insulating elements is not in a thermal path of either (i) heat flow from the at least one heat source to the plurality of thermoelectric assemblies or (ii) heat flow to the at least one heat sink from the plurality of thermoelectric assemblies.

14. The thermoelectric system of claim 13, wherein the plurality of electrically insulating elements is not in a thermal path of the heat flow from the at least one heat source to the plurality of thermoelectric assemblies and the plurality of electrically insulating elements is not in a thermal path of the heat flow to the at least one heat sink from the plurality of thermoelectric assemblies.

15. The thermoelectric system of claim 14, wherein the plurality of electrically insulating elements is positioned relative to the plurality of thermoelectric assemblies such that the plurality of electrically insulating elements does not impede the heat flow from the at least one heat source to the plurality of thermoelectric assemblies and the plurality of electrically insulating elements does not impede the heat flow to the at least one heat sink from the plurality of thermoelectric assemblies.

16. The thermoelectric system of claim 13, wherein each thermoelectric assembly of the plurality of thermoelectric assemblies comprises:
a first heat exchanger in thermal communication with the at least one heat source;
a second heat exchanger in thermal communication with the at least one heat sink;
at least one first thermoelectric element having a first doping type and in thermal communication and in electrical communication with both the first heat exchanger and the second heat exchanger; and
at least one second thermoelectric element having a second doping type different from the first doping type, the at least one second thermoelectric element in thermal communication and in electrical communication with the first heat exchanger.

17. The thermoelectric system of claim 16, wherein the at least one second thermoelectric element of a thermoelectric assembly of the plurality of thermoelectric assemblies is in thermal communication and in electrical communication with the second heat exchanger of an adjacent thermoelectric assembly of the plurality of thermoelectric assemblies.
